(19) United States
(12) Patent Application Publication
(10) Pub. No.: US 2005/0079418 A1
(43) Pub. Date: Apr. 14, 2005

(54) In-line deposition processes for thin film battery fabrication

(75) Inventors: Tommie W. Kelley, Coon Rapids, MN (US); Steven D. Theiss, Woodbury, MN (US); Dawn V. Muyres, St. Paul, MN (US); Paul F. Baude, Maplewood, MN (US); Michael A. Haase, St. Paul, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 10/685,725

(22) Filed: Oct. 14, 2003

(51) Int. Cl. H01M 6/00; H01M 4/58; B05D 5/12; C23C 16/26

(52) U.S. Cl. 429/231.95; 29/623.1; 427/115; 427/282; 427/249.1; 118/504

(57) ABSTRACT

In one embodiment, the invention is directed to aperture mask deposition techniques using aperture mask patterns formed in one or more elongated webs of flexible film. The techniques involve sequentially depositing material through mask patterns formed in the film to define layers, or portions of layers, of the thin film battery. A deposition substrate can also be formed from an elongated web, and the deposition substrate web can be fed through a series of deposition stations.

### TECHNICAL FIELD

The invention relates to fabrication of thin film batteries, including lithium, lithium-ion and lithium-free thin film batteries, and more particularly to deposition techniques using flexible aperture masks.

### BACKGROUND

Thin film batteries have several advantages over conventional battery technology in that battery cell components can be prepared as thin, e.g. 1 micron, sheets built up in layers. The area of the sheets can be varied from sizes achievable with present lithographic techniques to a few square meters providing a wide range in battery capacity. Deposition of thin films places the anode close to the cathode resulting in high current density, high cell efficiency and a great reduction in the amount of materials used. This is because the transport of ions is easier and faster in thin film layers since the distance the ions must move is lessened.

However, the successive deposition of the component layers often use separate deposition and patterning steps, and typically involve etching or lithographic techniques where a layer is deposited, then patterned by photolithography, and unwanted material is subsequently removed. These subtractive processes can be wasteful, environmentally unfriendly, solvent intensive, damaging to reactive layers, and therefore add considerably to the complexity and cost of production of a thin film battery.

### SUMMARY

In general, the invention is directed to deposition techniques using aperture mask patterns formed in one or more sheets or elongated webs of flexible film. As used herein, “web” is inclusive of sheets, i.e. finite single sheets. The techniques involve sequentially depositing material through aperture mask patterns formed in the webs to define layers, or portions of layers, of a thin film battery. A deposition substrate can also be formed from an elongated web, and the deposition substrate web can be fed through a series of deposition stations. Each deposition station may have its own elongated web formed with aperture mask patterns. In some embodiments, each elongated web of aperture mask patterns travels in a direction perpendicular to the deposition substrate web. In this manner, the thin film battery fabrication process can be performed in-line. Moreover, the process can be automated to reduce human error and increase throughput.

In some embodiments, thin film batteries can be created solely using aperture mask deposition techniques, without requiring any of the etching or photolithography steps typically used to form thin film battery patterns. Aperture mask deposition techniques can be particularly useful in fabricating thin film battery elements for electronic devices and circuits where space and weight for the batteries is severely limited. In addition, the techniques can be advantageous in the fabrication of integrated circuits incorporating thin film batteries.

In one embodiment, the invention is directed to a repositionable aperture mask comprising an elongated web of flexible film, and a deposition mask pattern formed in the film, wherein the deposition mask pattern defines deposition apertures that extend through the film. The elongated web may be greater than approximately 50 centimeters or greater than approximately 100 centimeters or greater than approximately 10 meters, or greater than approximately 100 meters in length. The mask can be sufficiently flexible such that it can be wound into a roll without damage or forming a permanent bend. Also, the aperture mask may be repositionable; i.e. can be removed from a substrate surface, positioned at another location on a substrate surface, or positioned on another substrate surface. In some embodiments, the aperture mask is reusable. Aperture masks in this form can be used as part of an in-line deposition system.

In other embodiments, the invention is directed to in-line deposition systems and in-line deposition methods. For example, a system may include a first web of flexible film and a second web of flexible film, wherein the second web of film defines a deposition mask pattern. The system may also include a drive mechanism that moves at least one of the first and second webs relative to the other of the first and second webs, and a deposition unit that deposits onto the first web of film through the deposition mask pattern defined by the second web of film. Various in-line deposition methods are also described.

In additional embodiments, the invention further comprises a stretching step for aligning a deposition mask pattern with a substrate, or a previously deposited layer, in an in-line deposition system. Such a stretching step may also be used to compensate of water uptake, or non-uniformity of the pattern. For example, a stretching apparatus may include a first stretching mechanism to stretch the first web of film in a down-web direction, a cross-web direction, or both directions in order to align the deposition mask pattern formed in the first web of film with a deposition substrate. The deposition substrate may also form a web, or alternatively may be a conveyance web carrying a series of substrates. The second web of film may also be stretched in the down-web direction, cross-web direction, or both directions.

The method of the invention optionally includes the step of vapor depositing an encapsulant layer. Particularly for lithium thin film batteries, the metal lithium reacts rapidly upon exposure to atmospheric elements such as oxygen, carbon dioxide and water vapor. Thus, the lithium anode of a thin film battery may react in an undesirable manner upon exposure to such elements if the anode is not suitably protected. Other components of a thin film battery, such as a lithium electrolyte and cathode layers, also may benefit from protection from exposure to air although these components are commonly not as reactive as thin metal anode films.

The various embodiments of the invention can provide one or more advantages. For example, the invention can facilitate the fabrication of relatively small thin film battery elements using aperture mask deposition techniques. For example, the invention can reduce costs associated with thin film battery fabrication, by streamlining the thin film battery fabrication process such that deposition can be performed in-line, thin film batteries may be created more quickly and with a reduced number of handling steps. Moreover, by reducing human error, an automated process may produce more reliable thin film batteries than other processes. In this manner, an in-line process can promote increased yields. Further, arrays of multi-cell batteries may be produced, whereby several cells are connected in series or in parallel. Such connections may be made in the deposition of the battery layers, or may be made in additional processing steps. In such constructions, an encapsulant layer may be used as an insulating layer to electrically insulate adjacent cells.

Also, because the elongated web may be formed from polymeric material, the apertures can be created using laser ablation techniques. Laser ablation techniques may be faster and less expensive than other mask creation techniques. Also, inexpensive polymeric materials can allow the elongated web of masks to be disposable. Laser ablation techniques allow for the fabrication of small deposition apertures, i.e., with widths less than approximately 1000 microns, less than approximately 50 microns, less than approximately 20 microns, 10 microns, or even 5 microns. In addition, laser ablation techniques allow for the creation of deposition apertures separated by a small gap, i.e., less than approximately 1000 microns, less than approximately 50 microns, less than approximately 20 microns, or even less than approximately 10 microns. These small deposition apertures and small gaps can facilitate the fabrication of small thin film battery elements. Additionally, laser ablation techniques can facilitate the fabrication of aperture mask patterns over large surface areas allowing large area thin film batteries or widely spaced thin film battery elements to be fabricated.

Furthermore, the polymeric material of the flexible, repositionable aperture mask is often stretchable, which allows the mask to be stretched in order to better align the mask with the deposition substrate and possibly to control sag. Stretching techniques in the down-web direction, the cross-web direction, or both may be used to achieve quick and precise alignment of the elongated web of aperture masks relative to the deposition substrate material.

Details of these and other embodiments of the invention are set forth in the accompanying drawings and the description below. Other features, objects, and advantages of the invention will become apparent from the description and drawings, and from the claims.

### BRIEF DESCRIPTION OF DRAWINGS

FIG. 1 is a perspective view of an aperture mask wound into a roll.

FIG. 2 is an enlarged view of a portion of the aperture mask of FIG. 1.

FIG. 3 is a top view of an aperture mask according to embodiments of the invention.

FIG. 4 is a block diagram of a laser ablation system that can be used to ablate aperture mask webs.

FIGS. 5 and 6 are simplified illustrations of in-line aperture mask deposition processes.

FIG. 7 is a block diagram of an exemplary deposition station.

FIG. 8 is a block diagram of an exemplary in-line deposition system

FIG. 9 is a cross section of a thin film battery.

FIG. 10 is a top view of two thin film battery cells, connected in series.

FIG. 11 is cross section of the two cells of FIG. 10.

### DETAILED DESCRIPTION

The method for preparing a thin film battery comprises the steps of: providing a substrate, optionally depositing a cathode current collector, depositing a cathode layer, depositing an electrolyte layer, depositing an anode layer, optionally depositing an anode current collector layer; wherein at least one of said layers, preferably two or more layers, is vapor deposited through a flexible, repositionable shadow mask. The individual layers need not be formed or deposited in the order recited. For example, the anode and cathode current collector layers may be deposited concurrently.

As used herein, vapor deposition or vapor depositing steps are inclusive of sputtering, thermal evaporation, electron beam evaporation, chemical vapor depositing, metalorganic chemical vapor depositing, combustion chemical vapor depositing and plasma enhanced chemical vapor and pulsed laser deposition.

In one preferred embodiment, the method comprises the steps of a) providing a substrate; b) depositing a first and a second current collector layer on the surface of said substrate, said first and second current conductor layers being electrically separated on the substrate; c) depositing a cathode layer over said first current collector layer; d) depositing an electrolyte layer overlapping the cathode layer to extend upon said first current collector layer and to partially extend upon said substrate separating said first and second current collector layers; and e) depositing an anode layer over the remainder of said substrate separating said first and second current collector layers and in electrical contact with the electrolyte layer and the anode current collector, and f) optionally depositing an encapsulant layer over one or more of the previous layers. At least one, and preferably two or more, most preferably all such layers are vapor deposited by means of a flexible, repositionable polymeric aperture mask.

Useful substrates include flexible and rigid polymeric substrates, glass, silica, alumina, ceramic, metal foils, fibers, fabric, paper, woven or nonwoven materials, silicon or other semiconductors, and batteries. Semiconductor substrates include doped and undoped semiconductors, epitaxial semiconductor layers supported by a base semiconductor or insulator, as well as other semiconductor structures known in the art. The substrate may also comprise a separately provided thin film battery, to produce a stacked, multicell thin film battery. The substrate may also comprise a circuit or circuit element, such as a thin film transistor to produce an electronic device with an integral power source.

Useful materials for the cathode and anode current collectors include main group metals (including noble metals), metal alloys, metalloids, and carbon black. Preferred current collector materials include Cu, Ag, Pd, Pt and Au.

Useful materials for the anode deposited layers include lithium metal (for lithium thin film batteries) or a lithium intercalation material (for lithium ion batteries), gold, tin, tin/lead alloys or the “lithium-free” materials, whereby lithium metal is electroplated from the electrolyte in situ at the metal anode current collector upon the initial charge cycle of the battery. Other useful anode materials include SiTON, a silicon-tin oxynitride, such as SiSn_{0.9}ON_{1.9}, which may be deposited by rf magnetron sputtering of SnO₂—SiO₂ in N₂, SnNₓ (0<x<1.33), which may be deposited by reactive sputtering of Sn in an Ar+N₂ mixture, Sn₃N₄, Zn₃N₂, and InNₓ (0<x<1), which may be deposited by reactive sputtering of In in an Ar+N₂ mixture.

Useful materials for the cathode deposited layers include crystalline TiS₂, LiMn₂O₂, LiCo_{0.2}Ni_{0.8}O₂, LiV₃O₈, LiV₂O₅, LiV₃O₁₃, LiMnO₂, crystalline LiMnO₄, crystalline LiCoO₂, crystalline and amorphous V₂O₅, and nanocrystalline LiₓMn_{2-y}O₄. Preferred cathode materials include lithium transition metal oxides, exemplified by those disclosed in U.S. Pat. No. 5,858,324 and U.S. Pat. No. 5,900,385, and in published applications U.S. 2003/0027048 and U.S. 2003/0031931, each incorporated herein by reference.

Useful electrolyte materials include lithium phosphorus oxynitride, known as LiPON, which may be deposited by rf magnetron sputtering of Li₃PO₄ in N₂. A second useful electrolyte is the NASICON-type solid electrolytes of the formula Li₁₊ₓM′M″(PO₄)₃, where M′ and M″ are transition or non-transition metals with an average oxidation state lower than +4, as describe by M. Catti, Journal of Solid State Chemistry 156, 305-313 (2001) and M. Forsyth et al., Solid State Ionics 124, 213-219 (1999). A third useful class of electrolytes are the plasticized inorganic-organic polymer electrolytes as described by M Popall et al., Electrochemica Acta 46, 1499-1508 (2001), and Electrochemica Acta 43, 1155 (1998)

As shown in FIG. 1, flexible film 11A may be sufficiently flexible such that it can be wound to form a roll 15A without damage. The ability to wind flexible film 11A onto a roll provides a distinct advantage in that the roll of film 15A has a substantially compact size for storage, shipping and use in an inline deposition station. Also, flexible film 11A may be stretchable such that it can be stretched to achieve precise alignment. For example, the flexible film may be stretchable in a cross-web direction, a down-web direction, or both. In exemplary embodiments, flexible film 11A may comprise a polymeric film. The polymeric film may be comprised of one or more of a wide variety of polymers including polyimide, polyester, polystyrene, polymethyl methacrylate, polycarbonate, or other polymers. Polyimide is a particularly useful polymer for flexible film 11A.

Aperture mask 10A is subject to a wide variety of shapes and sizes. For example, in exemplary embodiments, a web of flexible film 11A is at least approximately 50 centimeters in length or 100 centimeters in length, and in many cases, may be at least approximately 10 meters, or even 100 meters in length. Also, the web of flexible film 11A may be at least approximately 3 cm in width, and less than approximately 200 microns in thickness, less than approximately 30 microns, or even less than approximately 10 microns in thickness.

In exemplary embodiments, aperture mask 10A as shown in FIG. 1 is formed from a polymer material. The use of polymeric materials for aperture mask 10A can provide advantages over other materials, including ease of fabrication of aperture mask 10A, reduced cost of aperture mask 10A, and other advantages. As compared to thin metal aperture masks, polymer aperture masks are much less prone to damage due to accidental formation of creases and permanent bends. Furthermore, some polymer masks can be cleaned with acids.

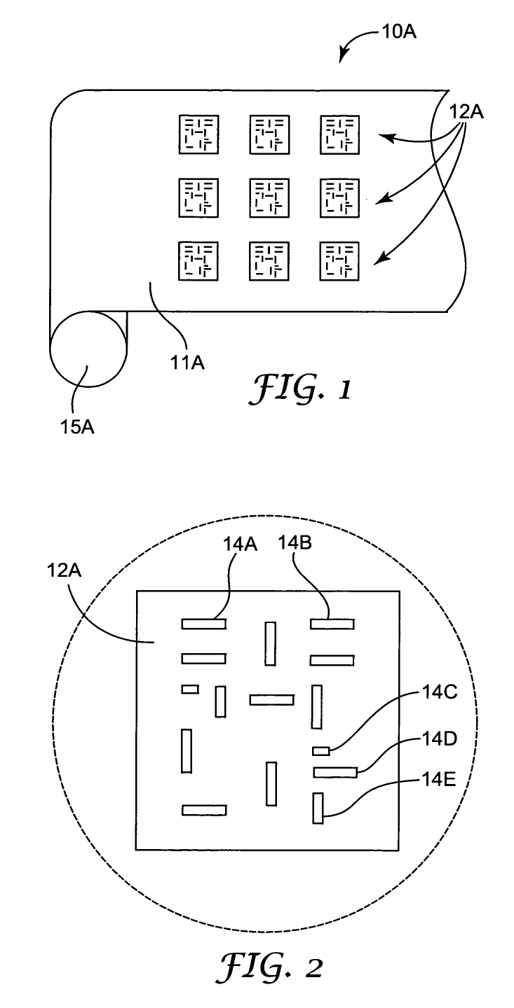

As shown in FIGS. 1 and 2, aperture mask 10A is formed with a pattern 12A that defines a number of deposition apertures 14 (only deposition apertures 14A-14E are labeled). The arrangement and shapes of deposition apertures 14A-14E in FIG. 2 are simplified for purposes of illustration, and are subject to wide variation according to the application and thin film battery layout envisioned by the user. Pattern 12A defines at least a portion of a thin film battery layer and may generally take any of a number of different forms. In other words, deposition apertures 14 can form any pattern, depending upon the desired thin film battery elements or thin film battery layer to be created in the deposition process using aperture mask 10A. For example, although pattern 12A is illustrated as including a number of similar sub-patterns, the invention is not limited in that respect, and each layer may be different.

Aperture mask 10A can be used in a deposition process, such as a vapor deposition process in which material is deposited onto a deposition substrate through deposition apertures 14 to define at least a portion of a thin film battery. Advantageously, aperture mask 10A enables deposition of a desired material and, simultaneously, formation of the material in a desired pattern. Accordingly, there is no need for a separate patterning step following or preceding deposition. In addition, because aperture mask 10A can be formed out of a flexible web of polymeric material, it can be used in an in-line process as described in greater detail below.

Aperture mask 10A may be used to create a variety of thin film batteries, which may be connected in series, in parallel, or may be connected to integrated circuits. For example a thin film battery may be used to provide power to an RFID circuit/transponder in order to extend read range or to provide continuous power to electronic memory use to store data in the RFID (radio frequency identification). The aperture mask may also be used to create a stack of battery cells, or a planar array of cells, both of which may be connected in series or parallel.

One or more deposition apertures 14 can be formed to have widths less than approximately 1000 microns, less than approximately 50 microns, less than approximately 20 microns, less than approximately 10 microns, or even less than approximately 5 microns. By forming deposition apertures 14 to have widths in these ranges, the sizes of the thin film battery elements may be reduced. Moreover, a distance (gap) between two deposition apertures (such as for example the distance between deposition aperture 14C and 14D) may be less than approximately 1000 microns, less than approximately 50 microns, less than approximately 20 microns or less than approximately 10 microns, to reduce the size of various thin film battery elements, or to reduce the size and extent of interconnects to other battery cells and/or integrated circuit elements.

Laser ablation techniques can be used to define pattern 12A of deposition apertures 14. Accordingly, formation of aperture mask 10A from a web of polymeric film can allow the use of fabrication processes that can be less expensive, less complicated, and/or more precise than those generally required for other aperture masks such as silicon masks or metallic masks. Moreover, because laser ablation techniques can be used to create pattern 12A, the width of pattern 12A can be made much larger than conventional patterns. For example, laser ablation techniques can facilitate the creation of pattern 12A such that a width of pattern 12A is greater than approximately a centimeter, greater than approximately 25 centimeters, greater than approximately 100 centimeters, or even greater than approximately 500 centimeters. These large masks can then be used in a deposition process to create thin film battery elements that are distributed over a large surface area and separated by large distances. Moreover, by forming the mask on a large polymeric web, the creation of large thin film batteries can be done in an in-line process.

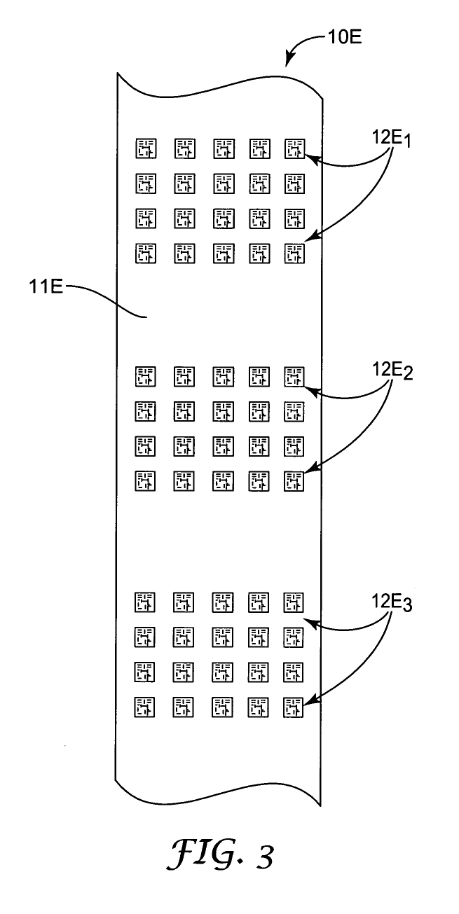

FIG. 3 is a top view of aperture mask 10E. As shown, aperture mask 10E is formed in a web of flexible material 11E, such as a polymeric material. Aperture mask 10E defines a number of patterns 12E₁-12E₃. In some cases, the different patterns 12E may define different layers of a thin film battery, and in other cases, the different patterns 12E define different portions of the same thin film battery layer. In some cases, stitching techniques can be used in which first and second patterns 12E₁ and 12E₂ define different portions of the same thin film battery feature. In other words, two or more patterns may be used in separate depositions to define a single thin film battery feature. Stitching techniques can be used, for example, to avoid relatively long deposition apertures, closed curves, or any aperture pattern that would cause a portion of the aperture mask to be poorly supported, or not supported at all. In a first deposition, one mask pattern forms part of a feature, and in a second deposition, another mask pattern forms the remainder of the feature.

In still other cases, the different patterns 12E may be substantially the same. In that case, each of the different patterns 12E may be used to create substantially similar deposition layers for different thin film batteries. For example, in an in-line web process, a web of deposition substrates may pass perpendicular to aperture mask 10E. After each deposition, the web of deposition substrates may move in-line for the next deposition. Thus, pattern 12E, can be used to deposit a layer on the web of deposition substrates, and then 12E₂ can be used in a similar deposition process further down the web of deposition substrates. Each portion of aperture mask 10E containing a pattern may also be reused on a different portion of the deposition substrate or on one or more different deposition substrates. More details of an in-line deposition system are described below.

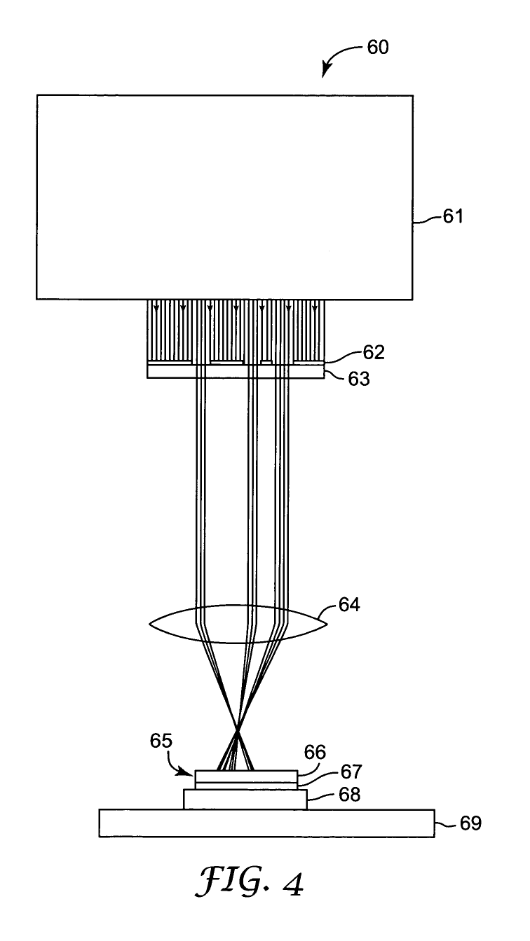

FIG. 4 is a block diagram of a laser ablation system that can be used to ablate aperture masks in accordance with the invention. Laser ablation techniques are advantageous because they can achieve relatively small deposition apertures and can also define patterns on a single aperture mask that are much larger than conventional patterns. In addition, laser ablation techniques may facilitate the creation of aperture masks at significantly lower cost than other conventional techniques commonly used to create metal or silicon aperture masks.

As illustrated in FIG. 4, laser ablation system 60 may be a projection laser ablation system utilizing a patterned ablation mask, although a shadow mask ablation system or phase mask ablation system could also be used. Projection imaging laser ablation is a technique that may be used for producing very small parts or very small structures on a surface of an object being ablated, the structures having sizes on the order of between one micron to several millimeters. In that case, light is passed through a patterned ablation mask and the pattern is imaged onto the object being ablated. Material is removed from the ablation substrate in the areas that receive radiation. Although the system is described using an ultraviolet (UV) laser, the illumination provided by the laser can be any kind of radiation having energy sufficient for ablation, such as infrared or visible light. Moreover, the invention can, in principle, be applied using radiation from sources other than lasers.

Laser 61 may be a KrF excimer laser emitting a beam with a short wavelength of light of approximately 248 nm. However, any type of excimer laser may be used, such as F₂, ArF, KrCl, or XeCl type excimer lasers. An excimer laser is particularly useful in creating small deposition apertures because an excimer laser can resolve smaller features and cause less collateral damage than lasers such as C0₂ lasers, which emit beams with a wavelength of approximately 10,600 nm. Also, excimer lasers can be used with most polymers that are transparent to light from lasers typically used for processing metals, such as Neodymium doped Yttrium Aluminum Garnet (Nd:YAG) lasers. Excimer lasers are also advantageous because at UV wavelengths, most materials, such as polymers, have high absorption. Therefore, more energy is concentrated in a shallower depth and the excimer laser provides cleaner cutting. Excimer lasers are pulsed lasers, the pulses ranging from 5-300 nanoseconds. Laser 61 may also be a tripled or quadrupled Nd:YAG laser, or any laser having pulses in the femtosecond range.

Ablation mask 63 may be a patterned mask having pattern 62 manufactured using standard semiconductor lithography mask techniques. The patterned portions of ablation mask 63 are opaque to UV light, while a support substrate of ablation mask is transparent to UV light. In one embodiment, the patterned portions comprise aluminum while the support substrate for ablation mask 63 is fused silica (SiO₂). Fused silica is a useful support material because it is one of the few materials that is transparent to mid and far UV wavelengths. Aluminum is useful as a patterning material because it reflects mid-UV light. A patterned dielectric stack is one alternative to aluminum.

Imaging lens 64 may be a single lens or an entire optical system consisting of a number of lenses and other optical components. Imaging lens 64 projects an image of the ablation mask, more specifically, an image of the pattern of light passing through the ablation mask onto surface of object to be ablated 65. The object to be ablated is a web of polymeric film 66, possibly including a material 67 formed on the backside. Some suitable polymers include polyimide, polyester, polystyrene, polymethymethacrylate and polycarbonate. The material 67 formed on the back side of the polymeric film 66 may be formed over the entire polymeric film, or alternatively formed only in the local area of the film being ablated.

Referring again to FIG. 4, table 69 supports and positions the object to be ablated 65. For example, object to be ablated 65 can be fixed into position on table 69, such as by vacuum chuck 68, static electricity, mechanical fasteners or a weight. Table 69 can position the object to be ablated 65 by moving the object 65 on the x, y and z axes as well as rotationally, such as along the z axis. Table 69 can move object 65 in steps down to approximately 5 nm, and more typically, approximately 100 nm, reproducible to an accuracy of approximately 500 nm. Computer control of table 69 can allow preprogramming of the movement of table 69 as well as possible synchronization of table movement with the emission of light from laser 61. The table may also be manually controlled, such as with a joystick connected to a computer.

In creating aperture masks for thin film battery fabrication, it can be advantageous to control the wall angle of the ablated deposition apertures so that the deposition apertures are suitable for material to be deposited through them. Accordingly, one may control the ablation so as to achieve an acceptable wall angle. A straight wall angle, i.e., a zero (0) degree wall angle, corresponds to a deposition aperture having walls that are perpendicular to the surface of the web of polymer film. In some cases, even a negative wall angle can be achieved, wherein the hole assumes a larger and larger diameter as the laser ablates through the web of polymer film.

In general, the aperture wall angle should be near zero to allow the closest possible spacing between apertures. However, if a large aperture mask is used in a deposition process with a small source, e.g., electron beam evaporation, a wall angle greater than zero is desirable to minimize parallax in regions of the mask where the deposition flux impinges the deposition substrate at an angle substantially different from perpendicular.

A number of factors can affect the wall angle. Accordingly these factors can be controlled to achieve an acceptable, or a desired wall angle. For example, the power density of the laser radiation at the substrate and the numerical aperture of the imaging system can be controlled to achieve an acceptable wall angle. Additional factors that may be controlled include the pulse length of the laser, and the ablation threshold of the object or material being ablated.

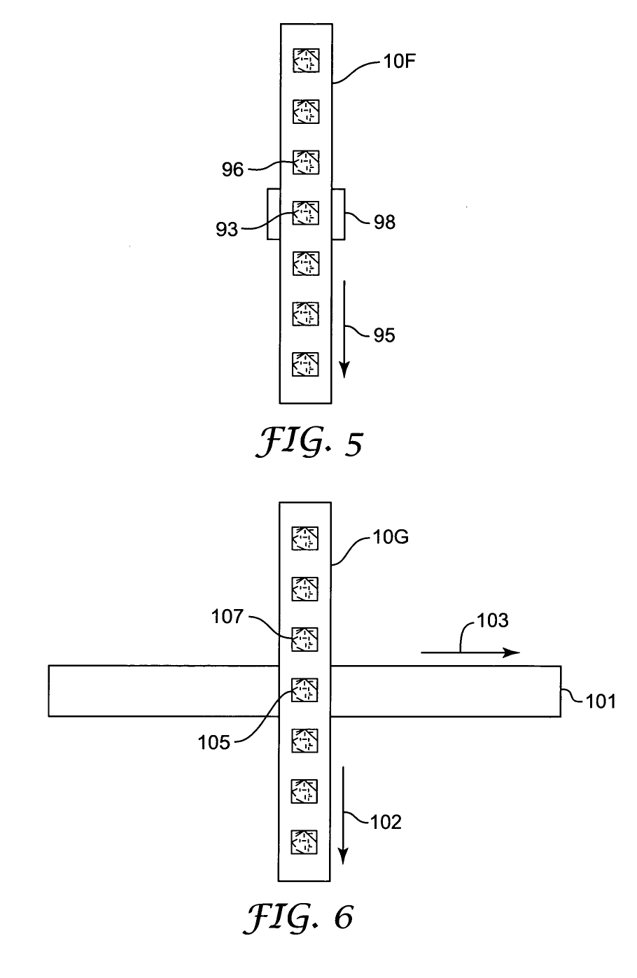

FIGS. 5 and 6 are simplified illustrations of in-line aperture mask deposition techniques. In FIG. 5, a web of polymeric film lOF formed with deposition mask patterns 96 and 93 travels past a deposition substrate 98. A first pattern 93 in the web of polymeric film 10F can be aligned with deposition substrate 98, and a deposition process can be performed to deposit material on deposition substrate 98 according to the first pattern 93. Then, the web of polymeric film 10F can be moved (as indicated by arrow 95) such that the a second pattern 96 aligns with the deposition substrate 98, and a second deposition process can be performed. The process can be repeated for any number of patterns formed in the web of polymeric film 10F. The deposition mask pattern of polymeric film 10F can be reused by repeating the above steps on a different deposition substrate or a different portion of the same substrate. The same mask pattern can be used proximate to, or touching, the substrate to deposit a first material, then moved away from the substrate to deposit a second material. In this case, the second deposited pattern will be larger than the first because of the angle of deposition and dispersion of the deposited material.

FIG. 6 illustrates another in-line aperture mask deposition technique. In the example of FIG. 6, the deposition substrate 101 may comprise a web. In other words, both the aperture mask 10G and the deposition substrate 101 may comprise webs, possibly made from polymeric material. Alternatively, deposition substrate web 101 may comprise a conveyance web carrying a series of discrete substrates. A first pattern 105 in the aperture mask web 10G can be aligned with deposition substrate web 101 for a first deposition process. Then, either or both the aperture mask web 10G and the deposition substrate web 101 can be moved (as indicated by arrows 102 and 103) such that a second pattern 107 in aperture mask web 10G is aligned with the deposition substrate web 101 and a second deposition process performed. If each of the aperture mask patterns in the aperture mask web 10G are substantially the same, the technique illustrated in FIG. 6 can be used to deposit similar deposition layers in a number of sequential locations along the deposition substrate web 101.

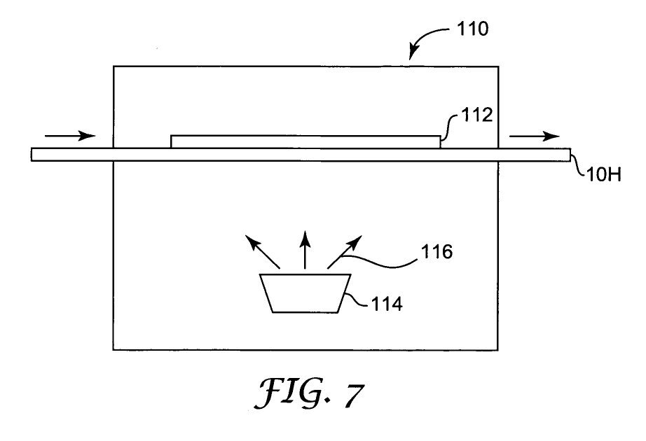

FIG. 7 is a simplified block diagram of a deposition station that can use an aperture mask web in a deposition process according to the invention. In particular, deposition station 110 can be constructed to perform a vapor deposition process in which material is vaporized and deposited on a deposition substrate through an aperture mask. The deposited material may be any material including anode current collector, cathode current collector, anode, cathode, electrolyte, and encapsulant. In addition, where a battery is integrated with a circuit, the deposited material may be any material used in the construction of integrated circuits, such as a semiconductor material, dielectric material, or conductive material.

A flexible web 10H formed with aperture mask patterns passes through deposition station 110 such that the mask can be placed in proximity with a deposition substrate 112. Deposition substrate 112 may comprise any of a variety of materials depending on the desired thin film battery to be created. For example, deposition substrate 112 may comprise a flexible material, such as a flexible polymer, e.g., polyimide or polyester, possibly forming a web. Any deposition substrates such as glass substrates, silicon substrates, rigid and flexible plastic substrates, metal foils, optionally coated with an insulating layer, or the like, could also be used. In any case, the deposition substrate may or may not include previously formed features.

Deposition station 110 is typically a vacuum chamber. After a pattern in aperture mask web 10H is secured in proximity to deposition substrate 112, material 116 is vaporized by deposition unit 114. For example, deposition unit 114 may include a boat of material that is heated to vaporize the material. The vaporized material 116 deposits on deposition substrate 112 through the deposition apertures of aperture mask web 10H to define at least a portion of a thin film battery layer on deposition substrate 112. Upon deposition, material 116 forms a deposition pattern defined by the pattern in aperture mask web 10H. Aperture mask web 10H may include apertures and gaps that are sufficiently small to facilitate the creation of small thin film battery elements using the deposition process as described above. Additionally, the pattern of deposition apertures in aperture mask web 10H may have a large dimension as mentioned above. Other suitable deposition techniques include e-beam evaporation, various forms of sputtering, and pulsed laser deposition.

However, when patterns in the aperture mask web 10H are made sufficiently large, for example, to include a pattern that has large dimensions, a sag problem may arise. In particular, when aperture mask web 10H is placed in proximity to deposition substrate 112, aperture mask web 10H may sag as a result of gravitational pull. This problem is most apparent when the aperture mask 10H is positioned underneath deposition substrate as shown in FIG. 7. Moreover, the sag problem compounds as the dimensions of aperture mask web 10H are made larger and larger.

The process may implement one of a variety of techniques to address the sag problem or otherwise control sag in aperture masks during a deposition process. For example, the web of aperture masks may define a first side that can removably adhere to a surface of a deposition substrate to facilitate intimate contact between the aperture mask and the deposition substrate during the deposition process. In this manner, sag can be controlled or avoided. In particular, a first side of flexible aperture mask 10H may include a pressure sensitive adhesive. In that case, the first side can removably adhere to deposition substrate 112 via the pressure sensitive adhesive, and can then be removed after the deposition process, or be removed and repositioned as desired.

One useful means to control sag, and to align the aperture mask, is to stretch the aperture mask. In that case, a stretching mechanism can be implemented to stretch the aperture mask by an amount sufficient to reduce, eliminate, or otherwise control sag. As the mask is stretched tightly, sag is reduced. In that case, the aperture mask may need to have an acceptable coefficient of elasticity. As described in greater detail below, stretching in a cross-web direction, a down-web direction, or both can be used to reduce sag and to align the aperture mask. In order to allow ease of alignment using stretching, the aperture mask can allow elastic stretching without damage. The amount of stretching in one or more directions may be greater than 0.1 percent, or even greater than 1 percent. Additionally, if the deposition substrate is a web of material, it too can be stretched for sag reduction and/or alignment purposes. Also, the aperture mask web, the deposition substrate web, or both may include distortion minimizing features, such as perforations, reduced thickness ares, slits, or similar features, which facilitate more uniform stretching. The slits can be added near the edges of the patterned regions of the webs and may provide better control of alignment and more uniform stretching when the webs are stretched. The slits may be formed to extend in directions parallel to the directions that the webs are stretched.

Further details regarding methods of use of flexible polymeric aperture masks may be found in Applicant's copending U.S. application Ser. Nos. 10/076,174 (published as US 2003/0150384), 10/076,003 (published as US 2003/0151118), and 10/076,005 (published as 2003/0152691), each incorporated herein by reference.

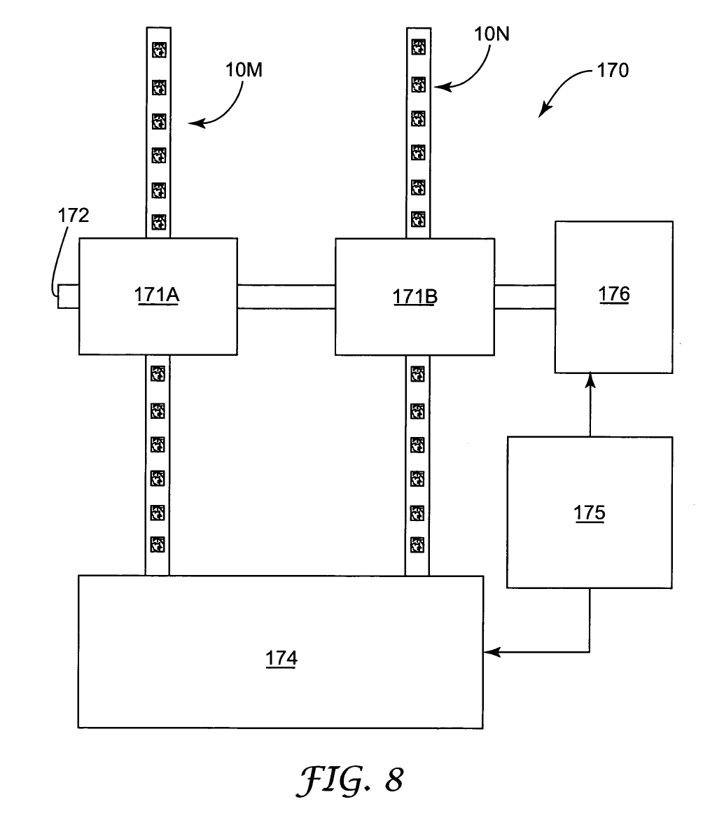

FIG. 8 is a block diagram of an in-line deposition system 170 according to an embodiment of the invention. As shown, in-line deposition system 170 includes a number of deposition stations 171A-171B (hereafter deposition stations 171). Deposition stations 171 deposit material on a deposition substrate web at substantially the same time. Then, after a deposition, the deposition substrate 172 moves such that subsequent depositions can be performed. Each deposition station also has an aperture mask web that feeds in a direction such that it crosses the deposition substrate. Typically, the aperture mask web feeds in a direction perpendicular to the direction of travel of the deposition substrate. For example, aperture mask web 10M may be used by deposition station 171A, and aperture mask web 10N may be used by deposition station 171B. Each aperture mask web 10 may include one or more of the features outlined above. Although illustrated as including two deposition stations, any number of deposition stations can be implemented in an in-line system according to the invention. Multiple deposition substrates may also pass through one or more of the deposition stations.

Deposition system 170 may include drive mechanisms 174 and 176 to move the aperture mask webs 10 and the deposition substrate 172, respectively. For example, each drive mechanism 174, 176 may implement one or more magnetic clutch mechanisms (or other means) to drive the webs and provide a desired amount of tension. Control unit 175 can be coupled to drive mechanisms 174 and 176 to control the movement of the webs in deposition system 170. The system may also include one or more temperature control units to control temperature within the system. For example, a temperature control unit can be used to control the temperature of the deposition substrate within one or more of the deposition stations. The temperature control may ensure that the temperature of the deposition substrate does not exceed 250 degrees Celsius, or does not exceed 125 degrees Celsius.

Additionally, control unit 175 may be coupled to the different deposition stations 171 to control alignment of the aperture mask webs 10 and the deposition substrate web 172. In that case, optical sensors and/or motorized micrometers may be implemented with stretching apparatuses in deposition stations 171 to sense and control alignment during the deposition processes. In this manner, the system can be completely automated to reduce human error and increase throughput. After all of the desired layers have been deposited on deposition substrate web 172, the deposition substrate web 172 can be cut or otherwise separated into a number of thin film batteries.

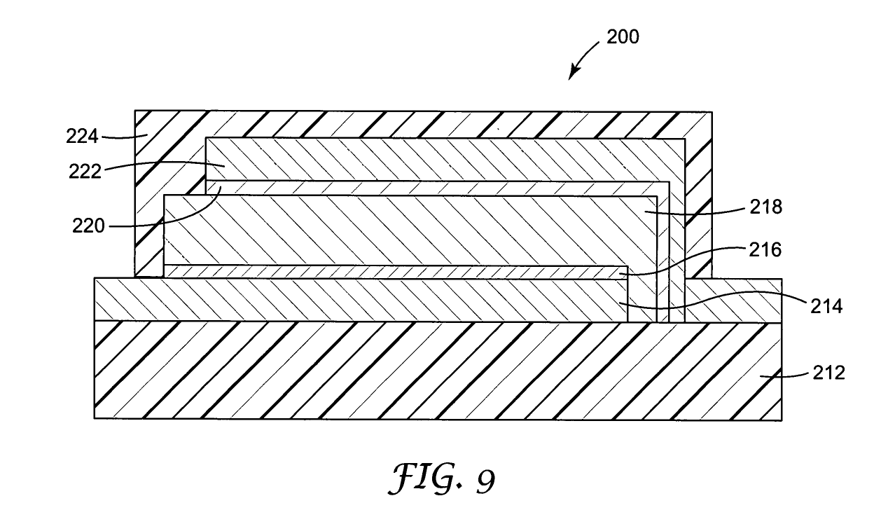

FIGS. 9-11 are cross-sectional and top views of exemplary thin film batteries that can be prepared. In accordance with the invention, thin film batteries 200 and 211 can be created without using photolithography in an additive or subtractive process. Instead, thin film batteries 200 and 211 can be created solely using aperture mask deposition techniques as described herein. Alternatively, one or more layers may be photolithographically patterned in an additive or subtractive process, with at least one of the layers being formed by the aperture mask deposition techniques described herein.

As shown in FIG. 9, thin film battery 200 is formed on a deposition substrate 212. Thin film battery 200 represents one embodiment in which all of the layers are deposited using an aperture mask and none of the layers are formed using etching or lithography techniques. As shown, battery 200 includes a substrate 212, and a cathode current collector 214 deposited thereon. The cathode 216 is in electrical contact with the cathode current collector 214 and the electrolyte 218. On the opposite face is an anode layer 220 in electrical contact with the electrolyte 218, and an anode current collector 222. All or part of the thin film battery may further comprise an encapsulant layer 224 for isolating the battery cell. The encapsulant layer may also serve as an insulating layer between, for example, individual cells of a multicell battery. Where desired, the encapsulant may serve as an insulator layer. For example, an insulator layer may be deposited between cells of a multilayer battery stack. Details regarding encapsulant layers may be found in Applicant's co-pending application U.S. Ser. No. 10/642,919, filed Aug. 13, 2003, incorporated herein by reference.

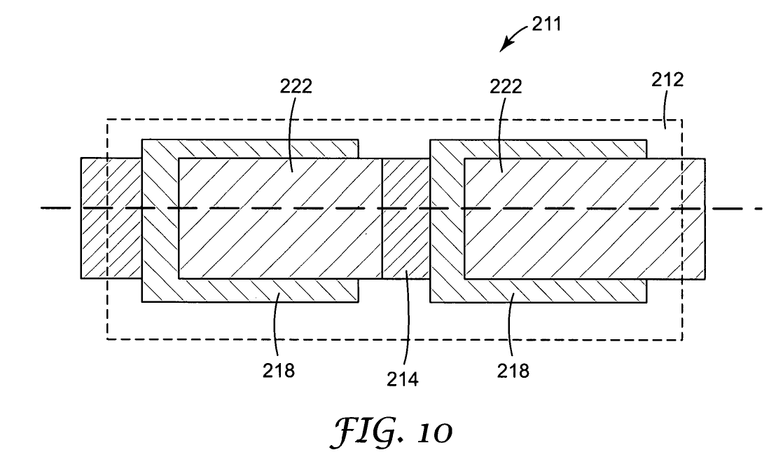

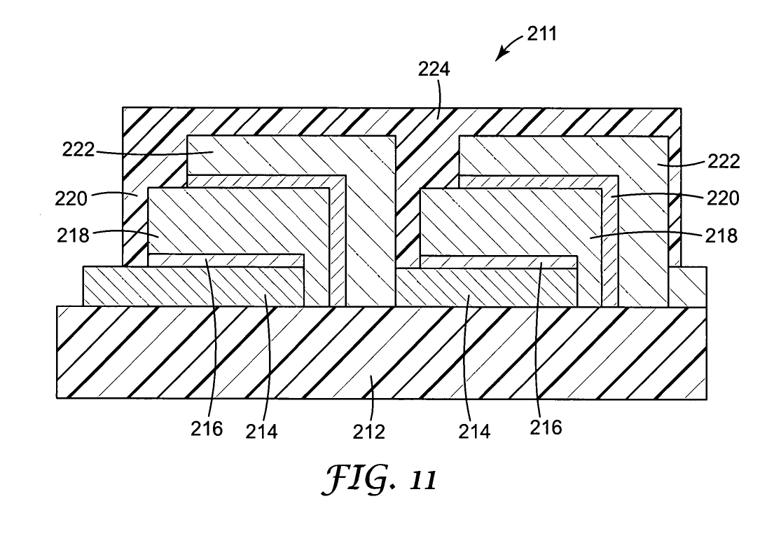

An array, i.e. a planar group of batteries may be prepared such as those shown in FIGS. 10 and 11. Herein two cells are connected in series as the anode current collector of the left hand cell is in electrical connection of the cathode current collector of the right hand cell. Alternatively, the cells can be connected in parallel by electrical connection of the cathode current collectors and the anode current collectors of adjacent cells.

In a typical sequence of steps to produce a thin film battery with a lithium anode, a substrate is provided, and the current collector layers deposited by dc magnetron sputtering. The cathode layer may then deposited on the cathode current collector and optionally annealed to crystallize the cathode layer. The anode current collector layer may then deposited typically by dc magnetron sputtering. The electrolyte layer, preferably a LiPON electrolyte may be applied by rf magnetron sputtering. The lithium anode may then be deposited, typically by thermal evaporation. Preferably a protective layer may be applied to the lithium anode, and other elements of the thin film battery.

In a typical sequence of steps to produce a thin film battery with a lithium ion anode, a substrate is provided, and the current collector layers deposited by dc magnetron sputtering. The cathode layer is then deposited on the cathode current collector, typically by rf magnetron sputtering, and then the electrolyte layer, preferably a LIPON electrolyte may be deposited by rf magnetron sputtering. The lithium-ion anode layer may then deposited, typically by magnetron sputtering. The anode current collector may then be deposited, typically by magnetron sputtering. Preferably a protective layer may be applied to the lithium anode, and other elements of the thin film battery.

In a typical sequence of steps to produce a thin film battery with a lithium free anode, a substrate is provided, and the cathode current conductor layer deposited by dc magnetron sputtering. The cathode layer is then deposited on the cathode current collector, typically by rf magnetron sputtering, and then the electrolyte layer, may be deposited by rf magnetron sputtering. The anode current collector may then be deposited, typically by magnetron sputtering. Preferably a protective layer may be applied to the anode, and other elements of the thin film battery. In the so-called “lithium-free” thin film batteries, a lithium anode is electroplated in-situ at the metal current collector upon the initial charge cycle of the battery

Further, a multicell, stacked column of batteries may be prepared using the process of the invention. Herein, a substrate may be deposited with layers of cathode, electrolyte, and anode, then the process repeated, with a second sequence of cathode, electrolyte, and anode with a layer of insulating material in-between successive cells. The associated anode and cathode current collectors of the successive cells may be connected in series or in parallel. The pattern of deposition may be such that the successive cells share a common anode current collector or cathode current collector. A stack of cells may be constructed with a third electrode layer, at the junction of two cells.

In another embodiment, the successive cells may be deposited so that the order of layers of the second cell is opposite that of the first cell, to form layers of cathode, electrolyte, and anode, then anode, electrolyte and cathode, with a layer of insulating material in-between successive cells. Alternatively, the stacked cells may share an anode. Again, the associated anode and cathode current collectors of the successive cells may be connected in series or in parallel. The pattern of deposition may be such that the successive cells share a common anode current collector or cathode current collector.

Aperture mask deposition techniques using an in-line deposition system represent one exemplary method of creating thin film battery. In that case, one or more deposition apertures in a flexible aperture mask 10 may define each layer of thin film batteries 200 and 211. Alternatively, one or more of the layers of the thin film battery may be defined by a number of different patterns in aperture mask web 10. In that case, stitching techniques, as mentioned above, may be used.

Thin film batteries are commonly connected to a variety of different circuits, including, for example, integrated circuits, an RFID integrated circuit, a circuit in an electronic display, electronic memory, a photovoltaic device, light emitting diodes, and the like. In the process of the invention, circuit elements may be deposited concurrently with deposition of the battery elements to produce integrated circuits with integral batteries. For example, the anode and cathode current collectors may be deposited as the source and drain, or gate electrodes of a thin film integrated circuit, and the further individual layers of each may be added by deposition through an aperture mask. Further detail on incorporating a thin film battery with an electronic device or an electronic circuit may be found in U.S. provisional applications 60/191,774, 60/225,134, 60/238,673, published as WO 01/73883, and each incorporated herein be reference.

The invention further provides a mask set for producing a thin film battery. A mask set may include a number of aperture masks for use in a deposition process, depending on the circuit or circuit element to be created in the deposition process. Masks form a “set” in the sense that each mask may correspond to a particular layer or set of layers or battery elements. Each aperture mask can be formed with a pattern of deposition apertures that define at least part of a layer of a thin film battery. For example, a first aperture mask may be formed with a first pattern of deposition apertures that define at least part of an anode layer, while a second aperture mask may be formed with a second pattern of deposition apertures that define at least part of a cathode layer, and a third aperture mask may be formed with a third pattern of deposition apertures that define at least part of an electrolyte layer. In other words, each mask in mask set may form only part of any given circuit layer. Additionally, any number of aperture masks may be included in the mask set depending on the number of layers in the thin film battery. The masks of the set may be used in any desired order,

In some cases, a mask set may define different layers of a thin film battery, and in other cases, a mask set may define different portions of the same battery layer or may define parts of other layers. For example, stitching techniques can be used to form interconnects in which first and second aperture masks of a set define different portions of the same battery layer. In other words, two or more masks may be used in separate depositions to define a single layer. Stitching techniques can be used, for example, to avoid relatively long deposition apertures, closed curves, or patterns that could cause portions of the aperture masks to be poorly supported. The solution is to form long lines and closed curves by “stitching” together the deposition patterns associated with two or more aperture masks to define a single circuit feature. In a first deposition, one mask forms part of a feature, and in a second deposition, another mask forms the remainder of the feature.

A number of embodiments of the invention have been described. For example, a number of different structural components and different aperture mask deposition techniques have been described for realizing an in-line deposition system. The deposition techniques can be used to create various thin film batteries solely using deposition, avoiding any chemical etching processes or photolithography. Moreover, the system can be automated to reduce human error and increase throughput. Nevertheless, it is understood that various modifications can be made without departing from the spirit and scope of the invention. For example, although some aspects of the invention have been described for use in a thermal vapor deposition process, the techniques and structural apparatuses described herein could be used with any deposition process including sputtering, thermal evaporation, electron beam evaporation, chemical vapor depositing, metalorganic chemical vapor depositing, combustion chemical vapor depositing and plasma enhanced chemical vapor and pulsed laser deposition. Thus, these other embodiments are within the scope of the following claims.

1. A method for preparing a thin film battery comprising the steps of:
a. providing a substrate
b. optionally depositing a cathode current collector
c. depositing a cathode layer,
d. depositing an electrolyte layer
e. depositing an anode layer
f. optionally depositing an anode current collector layer;
g. optionally depositing an encapsulant layer;
wherein at least one of said layers is vapor deposited through a flexible, repositionable, polymeric shadow mask.

2. The method of claim 1 wherein the steps are conducted in the order listed.

3. The method of claim 1, wherein the cathode and anode current collectors are deposited concurrently.

4. The method of claim 1 wherein said substrate layer is selected from rigid and flexible polymeric substrates, glass substrates, silicon substrates, silica substrates, paper substrates, woven substrates, nonwoven substrates, an integrated circuit and batteries.

5. The method of claim 1 wherein said cathode is a lithium transition metal oxide.

6. The method of claim 1 wherein said cathode is selected from amorphous V₂O₅, crystalline TiS₂, LiMn₂O₂, LiCo_{0.2}Ni_{0.8}O₂, LiCoO₂, LiV₃O₈, LiV₂O₅, LiV₃O₁₃, and LiMnO₂, LiMnO₄, LiCoO₂, V₂O₅, and LiₓMn_{2-y}O₄.

7. The method of claim 1 wherein said electrolyte is lithium phosphorus oxynitride.

8. The method of claim 1 wherein said anode layer is selected from lithium metal, lithium intercalation compounds, silicon-tin oxynitride, tin, tin/lead alloys and gold.

9. The method of claim 1 wherein said vapor depositing step further comprises positioning said aperture mask in proximity to said substrate.

10. The method of claim 1 wherein each of said depositing steps are vapor depositing steps.

11. The method of claim 1 comprising the steps of
a. providing a substrate,
b. aligning said substrate with a current collector mask,
c. vapor depositing a current collector layer onto the substrate,
d. aligning the substrate with an electrolyte mask,
e. depositing an electrolyte layer,
f. aligning the substrate with an anode mask,
g. depositing the anode layer, and
h. optionally depositing an encapsulant layer.

12. The method of claim 11 further comprising repeating, in a preselected sequence, steps b) though h) until the desired number of battery cells has been deposited to produce a multicell battery.

13. A method of claim 12, wherein said cells are connected in series.

14. A multicell battery of claim 12 wherein said cells are connected in parallel.

15. The method of claim 12 wherein a planar array of thin film batteries are produced on said substrate.

16. The method of claim 12 wherein a stacked column of thin film batteries are produced on said substrate.

17. The method of claim 16 wherein said array of batteries are connected in series.

18. The method of claim 16 wherein said array of batteries are connected in parallel.

19. The method of claim 1 wherein said vapor depositing steps are selected from sputtering, thermal evaporation, electron beam evaporation, chemical vapor depositing, metalorganic chemical vapor depositing, combustion chemical vapor depositing and plasma enhanced chemical vapor and pulsed laser deposition steps.

20. The method of claim 1 wherein said aperture mask comprises an elongated web of flexible film; and a deposition mask pattern formed in the film, wherein the deposition mask pattern defines deposition apertures that extend through the film that define at least a portion of a battery cell.

21. The method of claim 20, wherein said aperture mask is formed with a number of deposition mask patterns.

22. The method of claim 21 wherein each deposition mask pattern is substantially the same.

23. The method of claim 21 wherein said deposition mask pattern is formed with two or more different mask patterns.

24. The method of claim 1, wherein said aperture mask is sufficiently flexible such that it can be wound to form a roll.

25. The method of claim 1 wherein said polymeric aperture mask comprises a polymer selected from polyimide, polyester, polystyrene, polymethyl methacrylate, and polycarbonate polymers

26. The method of claim 1 further comprising
a first web of flexible substrate film;
a flexible polymeric aperture mask comprising a second flexible film,
wherein the polymeric aperture mask defines a deposition mask pattern that defines at least a portion of a thin film battery;
a drive mechanism that moves at least one of the first and second webs relative to the other of the first and second webs; and
a deposition unit that deposits onto the substrate through the deposition mask pattern defined by the polymeric aperture mask.

27. The method of claim 25, further comprising an alignment mechanism that aligns the deposition mask pattern of the polymeric aperture mask with the substrate prior to deposition.

28. The method of claim 27, wherein the alignment mechanism is a stretching apparatus that stretches the polymeric aperture mask to align the deposition mask pattern relative to the substrate.

29. The method of claim 27, wherein the alignment mechanism is a stretching apparatus that stretches the substrate film to align the deposition mask pattern relative to the polymeric aperture mask.

30. The method of claim 26, wherein the aperture mask is formed with a number of deposition mask patterns.

31. The method of claim 26, wherein each deposition mask pattern is substantially the same.

32. The method of claim 1 comprising:
positioning a substrate and an aperture mask in proximity to each other, wherein the aperture mask defines a deposition mask pattern; and
depositing an anode layer on the substrate film through the deposition mask pattern defined by the aperture mask to create at least a portion of a thin film battery.

33. The method of claim 1 comprising:
positioning a substrate and an aperture mask in proximity to each other, wherein the aperture mask defines a deposition mask pattern; and
depositing an electrolyte layer on the substrate through the deposition mask pattern defined by the aperture mask to create at least a portion of a thin film battery.

34. The method of claim 31, further comprising:
positioning a different area of the substrate and the deposition mask pattern of second aperture mask in proximity to each other; and depositing a cathode layer on the different area of the substrate film through the second deposition mask pattern.

35. The method of claim 1, further comprising:
sequentially positioning the substrate in proximity to each of a number of aperture masks formed with deposition mask patterns; and
sequentially depositing anode, electrolyte and cathode layers on the substrate through the deposition mask patterns to create a thin film battery.

36. The method of claim 33, further comprising creating a number of thin film batteries on the substrate film.

37. The method of claim 1 comprising:
a first web of substrate film;
an aperture mask comprising a second web of film, wherein the second web of film is formed with a number of deposition mask patterns;
an aperture mask comprising a third web of film, wherein the third web of film is formed with a number of deposition mask patterns;
a first deposition chamber, wherein the first and second webs of film feed past one another inside the first deposition chamber such that material can be deposited onto the first web of film through a deposition mask pattern of the second web of film; and
a second deposition chamber, wherein the first and third webs of film feed past one another inside the second deposition chamber such that material can be deposited onto the first web of film through a deposition mask pattern of the third web of film.

38. The method of claim 1, further comprising the step of depositing one or more layers of an integrated circuit, wherein at least one layer of the battery is shared with the integrated circuit.

39. The method of claim 36, wherein a current collector layer of the battery is shared with the source, drain or gate electrode of the integrated circuit.

40. A thin film battery prepared by the method of claim 1.

41. A thin film battery connected to an circuit prepared by the method of claim 36.

42. A mask set for producing a thin film battery comprising a first aperture mask formed with a first pattern of deposition apertures that define at least part of an anode layer, a second aperture mask formed with a second pattern of deposition apertures that define at least part of a cathode layer, and a third aperture mask formed with a third pattern of deposition apertures that define at least part of an electrolyte layer.
